(19) United States
(12) Patent Application Publication
(10) Pub. No.: US 2025/0380368 A1
(43) Pub. Date: Dec. 11, 2025

(54) WIRE MULTI PASS DISTRIBUTOR WITH SAFETY STRUCTURE

(71) Applicant: KELEI CUI, Xinyi (CN)

(72) Inventor: KELEI CUI, Xinyi (CN)

(21) Appl. No.: 19/227,853

(22) Filed: Jun. 4, 2025

(30) Foreign Application Priority Data
Jun. 6, 2024 (CN) 202421282091.8

(51) Int. Cl. H05K 5/02; H05K 7/14

(52) U.S. Cl. CPC H05K 5/0217; H05K 5/0247; H05K 7/1427

(57) ABSTRACT

A wire multi pass distributor with a safety structure is provided. The distributor includes a distributor body, an interior of the distributor body is provided with a negative connector and two positive connectors. A surface of the distributor body is provided with a recess, and an interior of the recess is connected to positions of the positive connectors. A plug-in fuse component is inserted into the interior of the recess, so the distributor body can protect the plug-in fuse component and maintain its own volume. Therefore, it can be used in a smaller space during use.

### CROSS-REFERENCE TO RELATED APPLICATIONS

This application claims priority to Chinese Patent Application No. 202421282091.8, filed on Jun. 6, 2024, which is hereby incorporated by reference in its entirety.

### TECHNICAL FIELD

The present disclosure relates to the field of multi-channel distributor technologies, and in particular, to a wire multi pass distributor with a safety structure.

### BACKGROUND

A multi-channel distributor, also known as a multiplexer, is a combinational logic circuit that sends the signal to be transmitted to a selected output terminal based on the different states of the input control signal. It is widely used in computers and control circuits. Depending on the purpose of use, the types of multi-channel distributors are also different. One-to-two distributors are a common type of multi-channel distributor. In the process of using a multi-channel distributor, excessive current in the circuit may cause damage to the distributor, and the cost of replacement is high. Therefore, fuses are usually installed in the circuit. At this time, extra considerations need to be made in circuit design. For special usage environments, there may be situations where fuses are difficult to install.

### SUMMARY

The main purpose of the present disclosure is to provide a wire multi pass distributor with a safety structure, which can effectively solve problems in background technology.

To achieve the above objectives, the technical solution adopted by the present disclosure is: a wire multi pass distributor with a safety structure, including a distributor body, where an interior of the distributor body is provided with a negative connector and two positive connectors, where a surface of the distributor body is provided with a recess, an interior of the recess is connected to the positive connectors, and a plug-in fuse component is inserted into the interior of the recess.

A packaging sleeve is fixedly provided on the surface of the distributor body, the plug-in fuse component is provided in the packaging sleeve, a plurality of convex rings are provided on a surface of the packaging sleeve, and a protective sleeve is sleeved on the surface of the packaging sleeve.

A connecting piece is fixedly provided on a surface of the protective sleeve, the connecting piece has hardness and deformation force, and the connecting piece has rebound force.

The recess has a “T” shape, the plug-in fuse component includes the housing, the connection heads are provided on two sides of the housing, the fuse is provided between the two connection heads, the connection heads are connected to the positive connectors, the housing is protruded from the surface of the distributor body.

The recess has a “T” shape, the plug-in fuse component includes the housing, the connection heads are provided on two sides of the housing, the fuse is provided between the two connection heads, the connection heads are connected to the positive connectors, the housing is flush with the surface of the distributor body.

The wireless warning device includes a main control circuit board, a power supply, a wireless communication module, a current sensing module, and an information processing module, where the power supply, the wireless communication module, the current sensing module, and the information processing module are all provided on the main control circuit board; the current sensing module is electrically connected to the fuse, and the power supply is a button battery.

Compared with existing technologies, the present disclosure has the following beneficial effects.

1. In the present disclosure, the protective sleeve, the packaging sleeve, and the plug-in fuse component are provided. When in use, the plug-in fuse component is inserted into the recess, and the safety structure of the distributor body renders it more convenient to use. At the same time, the surface of the packaging sleeve is sleeved with the protective sleeve, which is fixed to the surface of the packaging sleeve by friction. The protective sleeve protects the plug-in fuse component from accidental damage and to some extent prevents the plug-in fuse component from falling off.

2. In the present disclosure, by providing the distributor body and the plug-in fuse component, the plug-in fuse component is completely located inside the distributor body. Therefore, the distributor body can protect the plug-in fuse component and maintain its own volume, rendering it suitable for smaller spaces during use.

3. In the present disclosure, by providing the wireless warning device, power can be provided through the power supply module to achieve an independent system. The wireless communication module is used to give warnings to the monitoring personnel's mobile APP, ensuring that even those who are not in place can be aware of the occurrence of a short circuit at the moment of power outage.

### BRIEF DESCRIPTION OF DRAWINGS

FIG. 1 is a schematic diagram of an overall structure of a wire multi pass distributor with a safety structure according to the present disclosure.

FIG. 2 is a schematic diagram of a recess of the wire multi pass distributor with a safety structure according to the present disclosure.

FIG. 3 is a schematic structural diagram of an embodiment of the wire multi pass distributor with a safety structure according to the present disclosure.

FIG. 4 is a schematic diagram of another embodiment of the wire multi pass distributor with a safety structure according to the present disclosure.

FIG. 5 is a schematic diagram of an internal structure of a housing of the wire multi pass distributor with a safety structure according to the present disclosure.

FIG. 6 is a schematic diagram of a wireless warning device of the wire multi pass distributor with a safety structure according to the present disclosure.

Numeral reference: 1—distributor body; 2—negative connector; 3—positive connector; 4—recess; 5—packaging sleeve; 6—convex ring; 7—protective sleeve; 8—connecting piece; 9—housing; 10—connection head; 11—fuse; 1a—main control circuit board; 2a—power supply; 3a—current sensing module; 4a—information processing module; 5a—wireless communication module.

### DESCRIPTION OF EMBODIMENTS

In order to make the technical means, creative features, objectives and effects of the present disclosure easy to understand, the following will further elaborate on the present disclosure in combination with specific implementation modes.

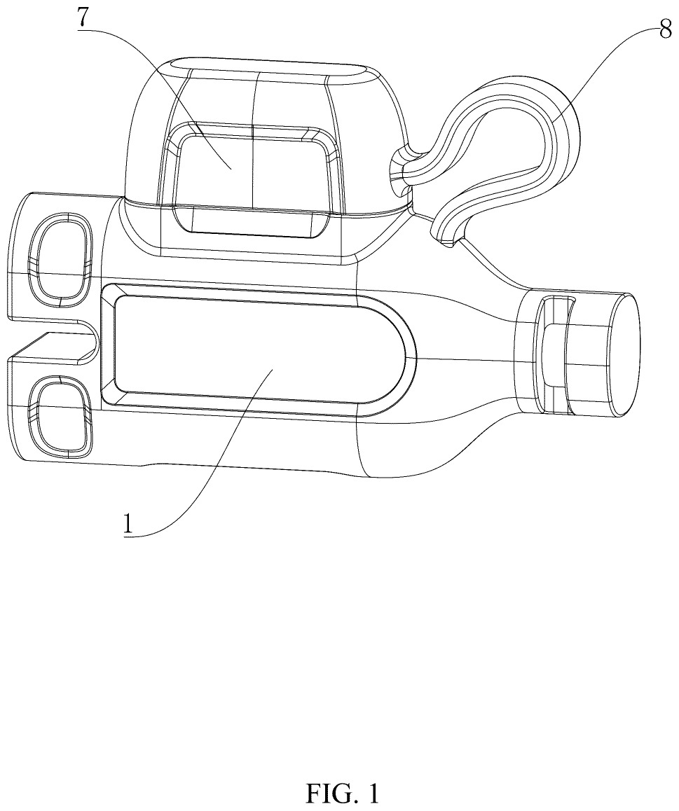

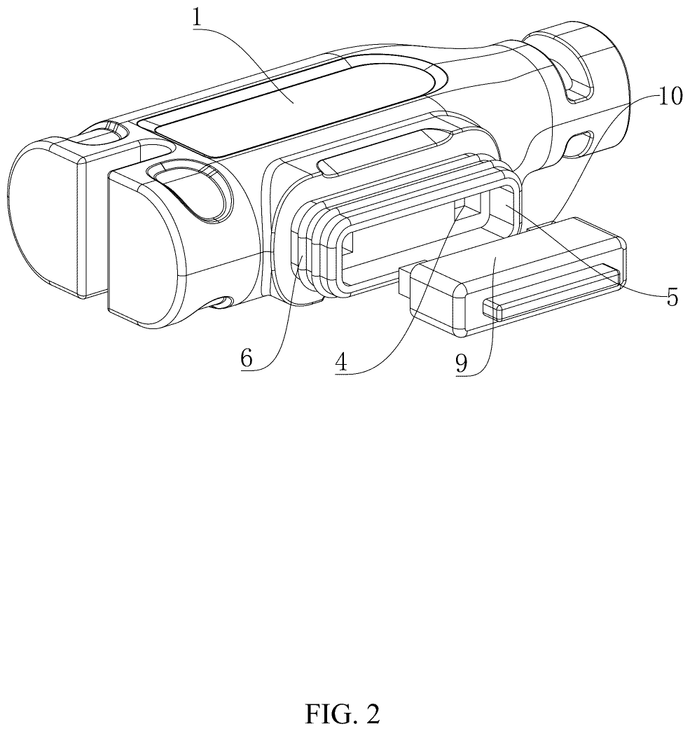

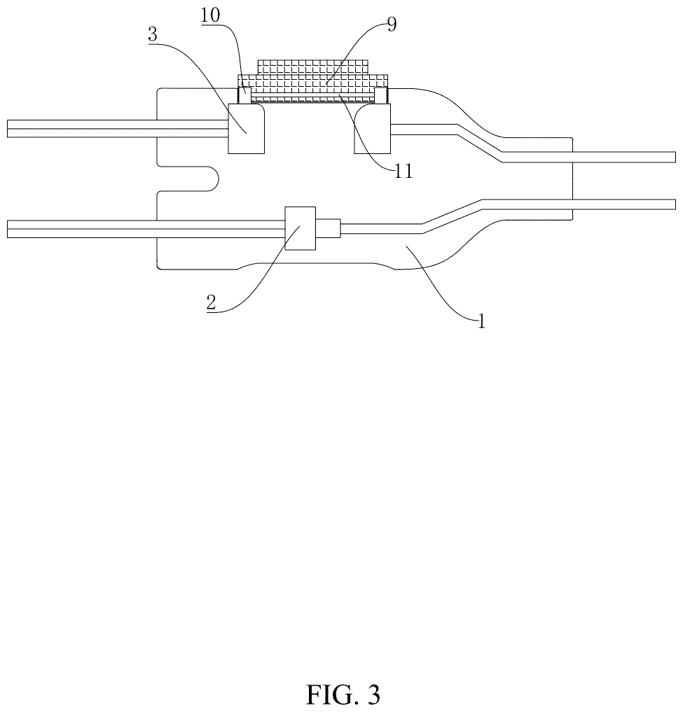

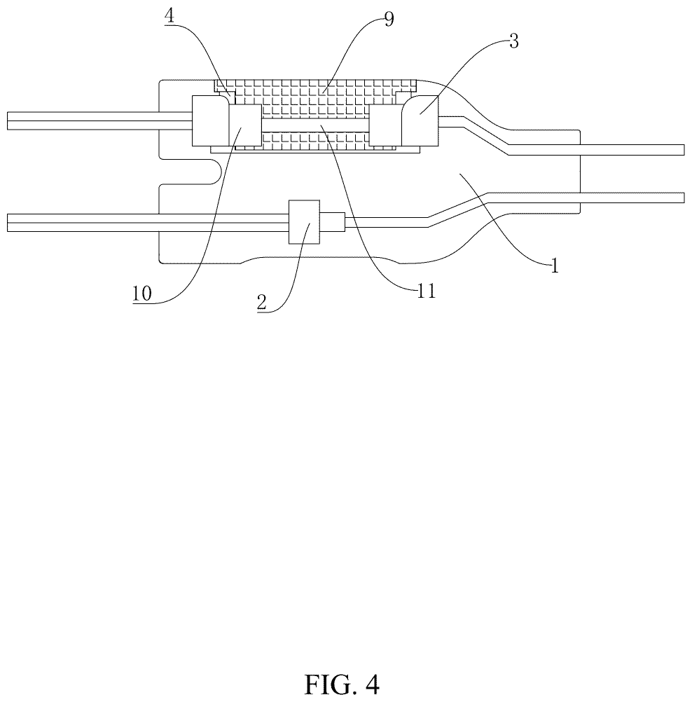

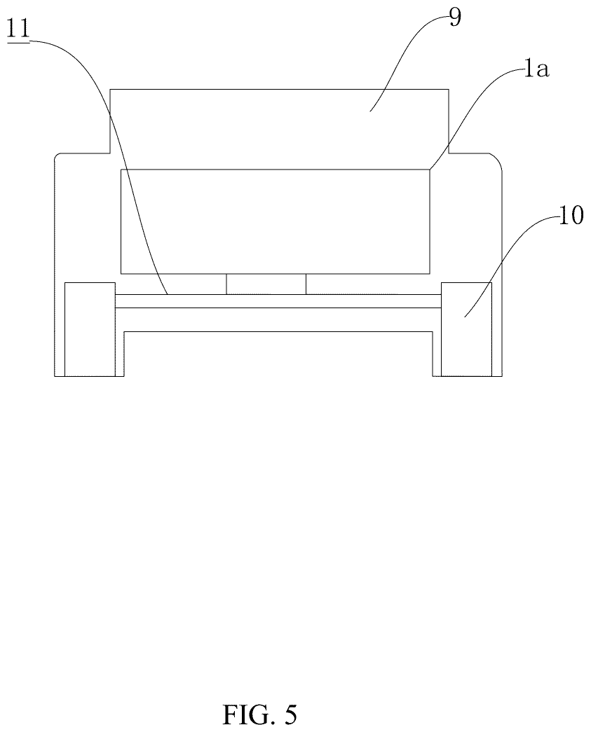

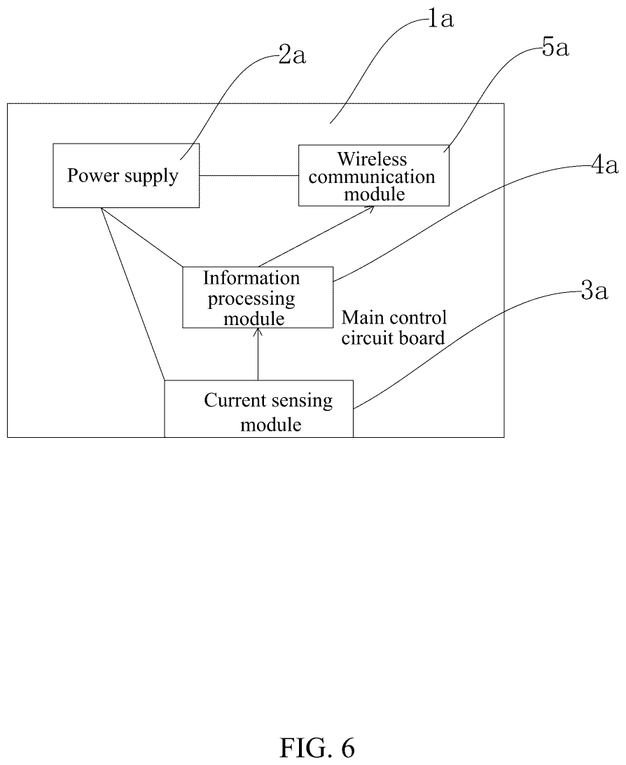

As shown in FIGS. 1-6, the technical solution adopted by the present disclosure to achieve the above objectives includes the following embodiments.

A wire multi pass distributor with a safety structure, including a distributor body 1. An interior of the distributor body 1 is provided with a negative connector 2 and two positive connectors 3. The negative connector 2 is configured to connect the negative wire, and the positive connectors 3 are configured to connect the positive wire. A gap is provided between the two positive connectors 3. A surface of the distributor body 1 is provided with a recess 4, and an interior of the recess 4 is connected to positions of the positive connectors 3. A plug-in fuse component is inserted into the interior of the recess 4. When the plug-in fuse component is inserted into the interior of the recess 4, it can contact the positive connectors 3 to form a path.

The surface of the distributor body 1 is fixedly provided with a packaging sleeve 5, and the packaging sleeve 5 is an integrated structure with the distributor body 1. The plug-in fuse component is provided inside the packaging sleeve 5, and a surface of the packaging sleeve 5 is provided with a plurality of convex rings 6. In an implementation model, the number of convex rings 6 is two, and the convex rings 6 are an integrated structure with the packaging sleeve 5. The surface of the packaging sleeve 5 is sleeved with a protective sleeve 7, and the protective sleeve 7 is fixed to the surface of the packaging sleeve 5 by friction. The protective sleeve 7 protects the plug-in fuse component from accidental damage and to some extent prevents it from falling off.

A surface of the protective sleeve 7 is fixedly provided with a connecting piece 8, and the connecting piece 8 has hardness and deformation force. The connecting piece 8 has a rebound force to prevent the protective sleeve 7 from falling off, and at the same time, an elastic force of the connecting piece 8 itself is used to ensure a stable installation of the protective sleeve 7.

The recess 4 has a “T” shape, and the plug-in fuse component includes a housing 9. Two connection heads 10 are provided at a lower end of the housing 9, and a fuse 11 is provided between the two connection heads 10. The connection heads 10 are connected to the positive connectors 3, and the housing 9 is protruded from the surface of the distributor body 1. When replacing the fuse 11, it is convenient to pull out the plug-in fuse component.

This embodiment is very convenient to use, especially for the replacement of plug-in fuse components. However, due to the protrusion of the packaging sleeve 5 and the protective sleeve 7, it requires a large usage space during use. Therefore, this embodiment needs to be selected according to an actual usage environment.

In an implementation mode, a wire multi pass distributor with a safety structure, including a distributor body 1. An interior of the distributor body 1 is provided with a negative connector 2 and two positive connectors 3. The negative connector 2 is configured to connect the negative wire, and the positive connectors 3 are configured to connect the positive wire. The surface of the distributor body 1 is provided with a recess 4, and the interior of the recess 4 is connected to positions of the positive connectors 3. A plug-in fuse component is inserted into the interior of the recess 4, and the recess 4 has a “T” shape. The plug-in fuse component includes a housing 9, and connection heads 10 are provided on two sides of the housing 9. A fuse 11 is provided between the two connection heads 10, and the connection heads 10 are connected to the positive connectors 3. Opposite ends of the positive connectors 3 are a curved surface to facilitate the insertion of the plug-in fuse component. The housing 9 is flush with the surface of the distributor body 1.

In this embodiment, the housing 9 is fixed by a frictional force between it and the recess 4. Since the plug-in fuse component is completely located inside the distributor body 1 at this time, the distributor body 1 can protect the plug-in fuse component and maintain its own volume. Therefore, it can be used in a smaller space during use. However, there is a problem of inconvenient disassembly and replacement, and external equipment needs to be used to pry open the housing 9. Therefore, it can be selectively used together according to actual situation.

It should be noted that the present disclosure is a wire multi pass distributor with a safety structure. When in use, the protective sleeve 7 is opened, and then the plug-in fuse component that needs to be replaced is inserted into the recess 4, or the housing 9 is directly pried open to replace the plug-in fuse component. When the external current is too high, the fuse 11 inside the plug-in fuse component will be burned out, thereby protecting the distributor body 1.

Besides that, considering that when there is no one on site, short circuits or other situations can cause the fuse to burn out, although it can cause the equipment to stop using, it requires waiting for someone to discover it before further processing, which is relatively time-consuming.

A wireless warning device is embedded in the housing 9, so that a main control circuit board 1a, a power supply 2a, a wireless communication module 5a, a current sensing module 3a, and an information processing module 4a of the wireless warning device are all provided in the housing 9. The power supply 2a is configured to supply power to the main control circuit board, and at the same time, the wireless communication module 5a, the current sensing module 3a, and the information processing module 4a provided on the main control circuit board 1a can also be powered, thereby forming an autonomous power supply system as a whole without the need for external power supply. By electrically connecting the current sensing module 3a to a fuse 11, when the distributor is working, the current sensing module 3a can also be real-time feedback to the information processing module 4a through transmission of the current passing through the sensing resistor wire 11 via the circuit. When the current sensing module 3a fails to detect the current, the information processing module 4a will transmit the signal to the wireless communication module 5a, and the wireless communication module 5a will directly send the signal to a monitor's mobile app. The monitor can immediately know if the device is short circuited or the fuse is blown, thereby playing a fast-warning role. The power supply 2a is a button battery, which can facilitate quick replacement of the power supply at a later stage.

The above displays and describes the basic principles, main features, and advantages of the present disclosure. Those skilled in the art should understand that the present disclosure is not limited by the above embodiments. The above embodiments and the description in the specification only illustrate the principles of the present disclosure. Without departing from the spirit and scope of the present disclosure, there will be various changes and improvements to the present disclosure, all of which fall within the scope of the present disclosure. The protection scope required by the present disclosure is defined by the attached claims and their equivalents.

What is claimed is:

1. A wire multi pass distributor with a safety structure, comprising a distributor body, wherein an interior of the distributor body is provided with a negative connector and two positive connectors,
wherein a surface of the distributor body is provided with a recess, an interior of the recess is connected to the positive connectors, and a plug-in fuse component is inserted into the interior of the recess.

2. The wire multi pass distributor according to claim 1, wherein a packaging sleeve is fixedly provided on the surface of the distributor body,
the plug-in fuse component is provided in the packaging sleeve,
a plurality of convex rings are provided on a surface of the packaging sleeve, and a protective sleeve is sleeved on the surface of the packaging sleeve.

3. The wire multi pass distributor according to claim 2, wherein a connecting piece is fixedly provided on a surface of the protective sleeve, the connecting piece has hardness and deformation force, and the connecting piece has rebound force.

4. The wire multi pass distributor according to claim 1, wherein the recess has a “x” shape, the plug-in fuse component comprises a housing, two connection head is provided at a lower end of the housing, a fuse is provided between the two connection heads,
the connection heads are connected to the positive connectors, and the housing is protruded from the surface of the distributor body.

5. The wire multi pass distributor according to claim 1, wherein the recess has a “T” shape, the plug-in fuse component comprises the housing,
the connection heads are provided on two sides of the housing,
the fuse is provided between the two connection heads,
the connection heads are connected to the positive connectors,
the housing is flush with the surface of the distributor body.

6. The wire multi pass distributor according to claim 5, wherein the plug-in fuse component further comprises a wireless warning device for inducing current of a fuse, and the wireless warning device is provided in the housing.

7. The wire multi pass distributor according to claim 6, wherein the wireless warning device comprises a main control circuit board, a power supply, a wireless communication module, a current sensing module, and an information processing module,
wherein the power supply, the wireless communication module, the current sensing module, and the information processing module are all provided on the main control circuit board;
the current sensing module is electrically connected to the fuse.

8. The wire multi pass distributor according to claim 7, wherein the power supply is a button battery.
